(19) United States
(12) Patent Application Publication
(10) Pub. No.: US 2025/0003849 A1
(43) Pub. Date: Jan. 2, 2025

(54) SYSTEM FOR SUBMARINE CABLE THERMAL-ELECTRICAL-MECHANICAL COMPOSITE TEST

(71) Applicant: KOREA ELECTROTECHNOLOGY RESEARCH INSTITUTE, Changwon-si (KR)

(72) Inventors: Jin Wook CHOE, Changwon-si (KR); Hae Jong KIM, Changwon-si (KR); Ik Su KWON, Changwon-si (KR); Seung Won LEE, Changwon-si (KR); Byung Bae PARK, Changwon-si (KR)

(21) Appl. No.: 18/883,837

(22) Filed: Sep. 12, 2024

Related U.S. Application Data
(63) Continuation of application No. PCT/KR2023/010210, filed on Jul. 17, 2023.

(30) Foreign Application Priority Data
Jun. 7, 2023 (KR) 10-2023-0073060

(51) Int. Cl. G01N 3/56; G01N 3/08; G01N 25/72; H01B 7/14

(52) U.S. Cl. CPC G01N 3/567; G01N 3/08; H01B 7/14; G01N 25/72; G01N 2203/0019; G01N 2203/0266

(57) ABSTRACT

Disclosed is a system capable of simultaneously performing a thermal test, an electrical test, and a mechanical test in an environment similar to the installation environment of a dynamic cable. The system includes a seawater tank module configured to form a seawater environment for a test cable, a mechanical test module configured to perform mechanical aging of the test cable according to an actuator operation, an electrical test module configured to perform electrical aging of the test cable by applying a voltage to each of opposite ends of the test cable, a thermal test module configured to perform thermal aging by applying a current to a dummy cable formed independently of the test cable, and a control module configured to perform data input, control processing, monitoring, and storage of the seawater tank module, the mechanical test module, the thermal test module, and the electrical test module.

### REFERENCE TO RELATED APPLICATIONS

This is a continuation of International Patent Application PCT/KR2023/010210 filed on Jul. 17, 2023, which designates the United States and claims priority of Korean Patent Application No. 10-2023-0073060 filed on Jun. 7, 2023, the entire contents of which are incorporated herein by reference.

### FIELD OF THE INVENTION

The present disclosure relates, in general, to a system for a submarine cable thermal-electrical-mechanical composite test and, more particularly, to a system capable of simultaneously performing a thermal test, an electrical test, and a mechanical test in an environment similar to the installation environment of a dynamic cable.

### BACKGROUND OF THE INVENTION

For submarine cables applied to offshore wind power, performance verification is required as an evaluation test for mechanical stress, electrical stress, and thermal stress before installation of the submarine cables.

A conventional typical submarine cable applied to offshore wind power as a static cable is installed on the seabed, and is installed inside a J-tube metal pipe when installed in a fixed offshore wind generator, etc. and does not move.

Accordingly, since the static cable is subject to mechanical stress only during production, transportation, and installation, it is acceptable to separately conduct a mechanical test to evaluate the mechanical stress occurring in onshore and offshore environments and electrical and thermal tests to evaluate electrical and thermal stresses occurring in a submarine environment during operation.

To describe this in detail, as shown in FIG. 1(a), the process of a static cable type test is performed in an order in which an electrical test is performed after a tensile stress test and a tensile bending test, etc. are performed to verify whether mechanical stress occurring during production, transportation, and installation affects the performance of a submarine cable.

That is, after each mechanical test for mechanical stress applied during production, transportation, and installation on one sample, a cable is visually inspected for breakage and damage, and when no abnormalities are found, an electrical test is conducted on this sample.

However, recently, a floating offshore wind turbine designed to float underwater is expanding in line with a floating offshore wind power generation project plan.

In this case, the floating offshore wind turbine uses a dynamic cable that floats underwater. Unlike the static cable that is fixed to the seabed, the dynamic cable experiences continuous tension and bending due to underwater environmental factors such as waves, buoyancy, currents, and cable weight, etc.

That is, the dynamic cable is subject to continuous mechanical stress not only in a terrestrial environment such as production, transportation, and installation, but also in a marine environment after the installation.

Accordingly, for the test of the dynamic cable, currently, tests are conducted independently on two samples, as in the type test of FIG. 1 (b). One sample is subjected to electrical testing after undergoing mechanical stress tests for production, transportation, and installation environments, such as static cables, while the other sample is sequentially subjected to electrical and thermal tests and mechanical stress tests in a marine environment.

However, in the case of dynamic cables, mechanical, electrical, and thermal stresses are simultaneously formed due to a marine environment underwater, but tests to measure the electrical, thermal and mechanical stresses are performed separately on land, so the tests have the problem of producing results different from stresses caused by an actual usage environment.

In the same context as the conventional method, tests for the characteristics of dynamic cables are disclosed in Korean Patent No. 10-2508559 ‘FLOATING OFFSHORE WIND DYNAMIC CABLE POWER CORE TENSION-BENDING ROTATIONAL FATIGUE TEST STRUCTURE’ and Korean Patent No. 10-2282208 ‘FLOATING OFFSHORE WIND POWER DYNAMIC CABLE BENDING STIFFNESS TEST FACILITY’, but include the same problems as those pointed out above.

That is, the mechanical, electrical, and thermal stresses of an actual dynamic cable occur simultaneously in a usage environment, and thus in order to solve the above-mentioned problem, in a dynamic cable type test, it is preferable that mechanical, electrical, and thermal tests are simultaneously performed in an underwater environment.

Below, research papers on mechanical, electrical, and thermal stresses of dynamic cables in an underwater environment will be examined.

Papers, ‘Remnant Static Mechanical Stresses and Water Tree Ageing of XLPE Power Cables’ and ‘Water Tree Ageing of High Voltage XLPE Cable Insulation System under Combined Dynamic Mechanical and AC Electrical Stress’, experimented on the possibility of water tree improvement due to residual mechanical stresses generated during the manufacturing process of extruded XLPE power cables.

A single-core extruded XLPE power cable is largely divided into a core and an insulation layer. During rapid cooling after the processes of extrusion and curing during production, internal residual stresses remain due to difference in cooling speed between the inside and outside of the insulation layer. These internal residual stresses cause a water tree, which is a polymer failure behavior, due to the combined effects of mechanical and electrical stresses when the internal residual stresses are used in an underwater environment.

The above papers disclose tests that artificially create a harsh environment that cannot occur in an actual cable usage environment by extracting the core from the single-core extruded XLPE power cable, filling the inside and outside of the insulation layer with water, applying mechanical stress, and then observing the water tree.

Such studies generally have the problem that they cannot be applied to observing underwater stress in a dynamic cable, since a test subject and a test purpose are different in that the dynamic cable generally uses a three-core extruded XLPE power cable and an armor layer is formed on an outer layer thereof to counteract underwater mechanical stress.

That is, in study for water tree observation, although a mechanical test is conducted in an underwater environment, the test, in which the core is extracted from a single-core extruded XLPE power cable and only the insulation layer is tested, is extremely different from an actual dynamic cable installation environment experiment.

In addition, the experimental object of the study is a single-core extruded XLPE power cable, and a metal tube is inserted inside the insulation layer of the cable and is fixed to an actuator to apply a mechanical stress thereto while maintaining the shape of the insulation layer, and thus a stress unrelated to a mechanical stress applied to an actual dynamic cable is applied, and a thermal test in which a current is applied to the cable is not performed, so the study is only a laboratory-level study unrelated to the installation environment of the actual dynamic cable.

### SUMMARY OF THE INVENTION

Accordingly, the present disclosure has been made to solve the above problems, and the present disclosure is intended to propose a system for a submarine cable thermal-electrical-mechanical composite test, in which mechanical, electrical, and thermal stresses are allowed to be simultaneously applied to an actual dynamic cable after forming an environment similar to the installation environment of the actual dynamic cable.

In order to achieve the above objectives, according to one aspect of the present disclosure, there is provided a system for a submarine cable thermal-electrical-mechanical composite test, the system including: a seawater tank module configured to form a seawater environment for a test cable; a mechanical test module configured to perform mechanical aging of the test cable according to an actuator operation by forming a fixing end and an action end on the test cable; an electrical test module configured to perform electrical aging of the test cable by applying a voltage to each of opposite ends of the test cable; a thermal test module configured to measure heat of the dummy cable generated while applying a current to a dummy cable formed independently of the test cable and to apply the current to the test cable while monitoring the heat as generated heat of the test cable; and a control module configured to perform data input, control processing, monitoring, and storage of the seawater tank module, the mechanical test module, the thermal test module, and the electrical test module, so that mechanical, thermal, and electrical tests on a dynamic cable are simultaneously performed.

In the present disclosure, the seawater tank module may include: a seawater tank in which the test cable is immersed; and a storage tank connected to a pipe controlled by a control valve.

In addition, the fixing end and the action end may fixedly clamp an armor layer that protects an inner wire of the test cable.

In addition, in the mechanical test module, a vertical actuator that is formed on an upper end of the seawater tank and presses the test cable, and a horizontal actuator that performs a horizontal movement on a side of the action end may operate in cooperation with each other to simulate mechanical aging caused by water flow.

In addition, a pressing member that presses the test cable may be formed on the vertical actuator, wherein the pressing member may be formed to have a semicircular shape in a longitudinal direction of the test cable, and a semicircular inner groove conforming to the test cable may be formed on a surface of the pressing member in contact with the test cable.

In addition, the horizontal actuator may be driven on a rail formed in a longitudinal direction of the test cable, and thus a moving direction thereof may be restrained in the longitudinal direction of the test cable.

In addition, the control module may include: an input part configured to input necessary information for performing the submarine cable thermal-electrical-mechanical composite test; a current control part configured to monitor the current applied to the dummy cable and heat generated therein and to apply the current to the test cable based on an amount of the generated heat; a voltage control part configured to control a voltage applied to the test cable; a motion control part configured to control the actuator operation; a seawater control part configured to control a water level of the seawater tank module; and a memory part configured to store data acquired from the input part, the current control part, the voltage control part, the motion control part, and the seawater control part.

According to the system for a submarine cable thermal-electrical-mechanical composite test as a means of solving the above problem, a characteristic evaluation test in which mechanical, electrical, and thermal stresses are simultaneously applied to an actual dynamic cable after forming an environment similar to the installation environment of the actual dynamic cable is performed and accordingly, there is an effect of ensuring the reliability of evaluation results.

Accordingly, there are effects of ensuring the quality of submarine cables and improving durability thereof.

### BRIEF DESCRIPTION OF THE DRAWINGS

FIG. 1 (a) is a flowchart illustrating a process of a static cable type test, and FIG. 1 (b) is a flowchart illustrating a process of a conventional dynamic cable type test.

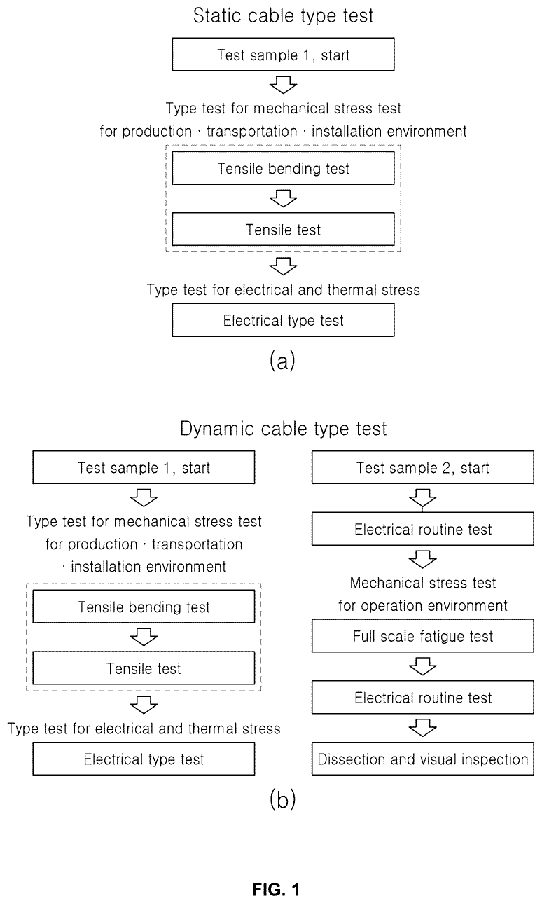

FIG. 2 is a configuration diagram simply illustrating a system for a submarine cable thermal-electrical-mechanical composite test of the present disclosure.

FIG. 3 is a configuration diagram of a control module of the present disclosure.

FIG. 4 is a view of the system for a submarine cable thermal-electrical-mechanical composite test according to an embodiment of the present disclosure.

FIG. 5 is a view illustrating clamping of a fixing end according to an embodiment.

FIG. 6 is a view of a seawater tank module and a vertical actuator according to an embodiment.

FIG. 7 is a view of a horizontal actuator of a mechanical test module according to an embodiment.

FIG. 8 is a view of a dummy cable according to an embodiment.

### DETAILED DESCRIPTION OF THE INVENTION

Hereinafter, the present disclosure will be described with reference to the drawings. When it is determined that a detailed description of a related known technology or configuration in describing the present disclosure may unnecessarily obscure the gist of the present disclosure, detailed description thereof will be omitted.

In addition, terms to be described later, which are terms defined in consideration of functions in the present disclosure, may vary depending on the intention or custom of a user or operator, so definitions thereof should be based on the whole contents of this specification in which the present disclosure is described.

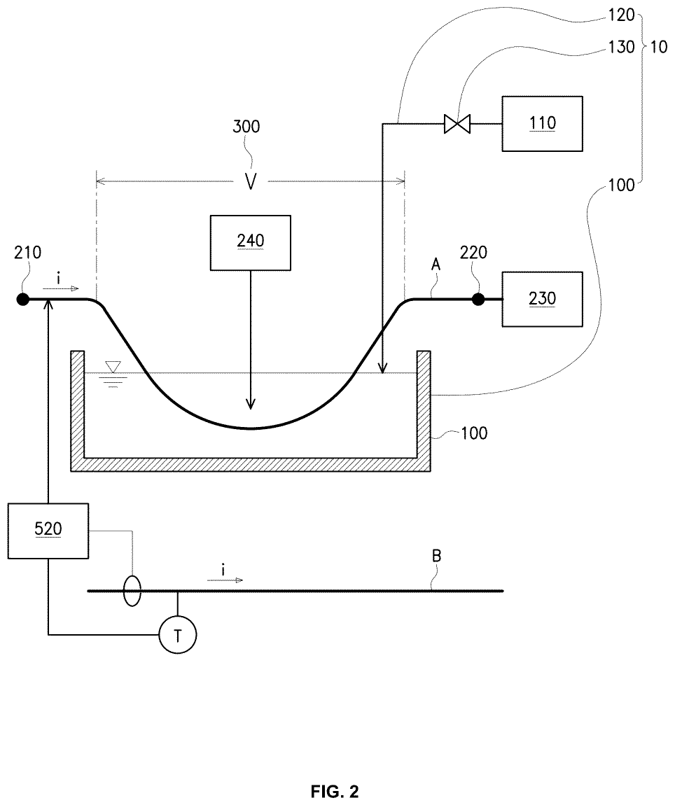

Hereinafter, configuration of a system for a submarine cable thermal-electrical-mechanical composite test of the present disclosure will be described with reference to the accompanying drawings. As illustrated in FIG. 2, to build a cable test system by creating an environment similar to the installation environment of an actual dynamic cable, the system of the present disclosure includes a seawater tank module 10, a mechanical test module 200, an electrical test module 300, a thermal test module 400, and a control module 500, and simultaneously performs mechanical, thermal and electrical tests on the dynamic cable.

The seawater tank module 10 is intended to form a seawater environment for a test cable A, and may include a seawater tank 100 of various sizes and shapes in which the test cable A is immersed depending on a test condition.

In this case, the seawater tank module 10 further includes a storage tank 110, and allows that water level in the seawater tank 100 to be maintained at a predetermined level according to the movement of the test cable A during a test.

For example, since the water level in the seawater tank 100 varies depending on the operating status of the mechanical test module 200 to be described later, it is preferable that the water level is adjusted in conjunction therewith.

The storage tank 110 is connected to the seawater tank 100 by a pipe 120 controlled by a control valve 130 to control the flow of seawater into and out of the seawater tank 100, thereby adjusting the water level of the seawater tank 100 to a predetermined height.

Accordingly, the test cable A forms an environment similar to the installation environment of an actual dynamic cable by forming a stable seawater environment.

In the mechanical test module 200, the test cable A includes a fixing end 210 and an action end 220 formed thereon and the mechanical aging of the test cable A is performed according to an actuator operation. More specifically, a first end of the test cable A is fixed by the fixing end 210, and a horizontal actuator 230 is formed on the action end 220 so that a second end of the test cable A is capable of performing a horizontal movement. The horizontal actuator 230 is driven on a rail formed in the longitudinal direction of the test cable A, and thus a moving direction thereof may be restrained in the longitudinal direction of the test cable A. Accordingly, the test cable A may be subjected to a tensile stress test in which a mechanical stress is applied thereto.

Furthermore, a vertical actuator 240 may be formed on the upper end of the seawater tank 100 and press the test cable A. Accordingly, the horizontal actuator 230 and the vertical actuator 240 may operate in cooperation with each other to simulate mechanical aging caused by water flow, so that a tensile bending test may be performed.

In this case, in the mechanical test module 200, the fixing end 210 and the action end 220 have a technical purpose of fixedly clamping an armor layer protecting an inner wire of the test cable A. In general, the armor layer is a steel wire formed on the outside of a dynamic cable to protect the inner wire thereof, and functions to minimize the application of a mechanical stress caused by waves, buoyancy, water current, and cable weight, etc. to the inner wire.

Unlike a paper on the conventional technology, in which a metal tube is inserted into the insulation layer and clamped to test a model cable with a conductor core removed and only an insulation layer left, in the present disclosure, an environment similar to the installation environment of an actual dynamic cable may be formed by cutting the same dynamic cable as actually installed to a test length and fixedly clamping the dynamic cable on the armor layer that blocks a mechanical stress.

That is, since a mechanical stress occurring in the dynamic cable in an actual underwater environment is directly transmitted to the armor layer, the system of the present disclosure has the advantage of allowing the mechanical stress to be applied to the armor layer, thereby allowing the observation of the status of the dynamic cable due to mechanical stress accumulation in an actual underwater environment.

The electrical test module 300 applies a voltage to the conductor of the test cable A so that electrical aging is performed.

The thermal test module 400 measures heat generated while applying a current to a dummy cable B formed independently of the test cable A, and applies the same current to the test cable while monitoring the generated heat.

That is, since a high voltage is applied to the test cable, direct heat measurement is impossible, and thus an induced current is generated in the dummy cable B, causing heat to be generated by Joule heating due to conductor resistance, and a temperature thereof is measured by a temperature sensor formed on the dummy cable B to estimate the temperature of the test cable A.

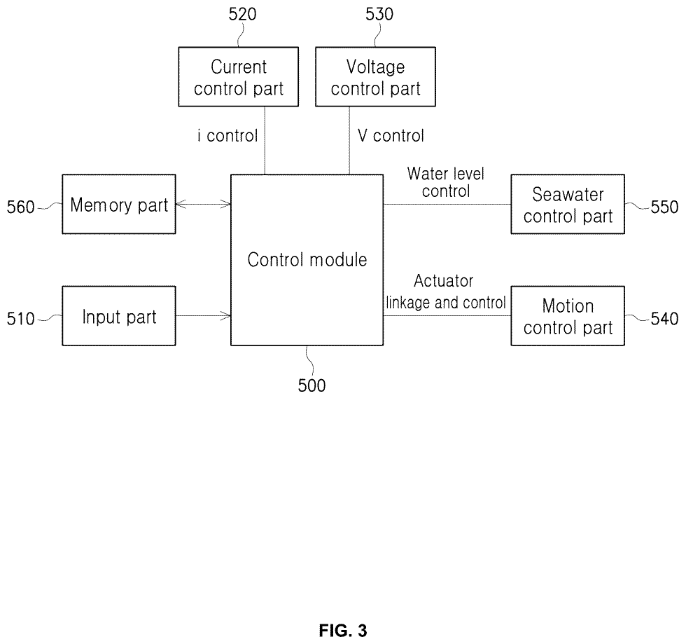

As illustrated in FIG. 3, the control module 500 performs data input, control processing, monitoring, and storage of the seawater tank module 10, the mechanical test module 200, the electrical test module 300, and the thermal test module 400.

More specifically, an input part 510 inputs necessary information for conducting a test through a PC in conjunction with the submarine cable thermal-electrical-mechanical composite test, a current control part 520 applies a current to the test cable while monitoring a current applied to the dummy cable and a temperature thereof, a voltage control part 530 controls and monitors a voltage applied to the test cable, a motion control part 540 controls the operations of the vertical actuator and the horizontal, and a seawater control part 550 controls the water level of the seawater tank module 10.

In addition, a memory part 560 stores data acquired from the input part 510, the current control part 520, the voltage control part 530, the motion control part 540, and the seawater control part 550.

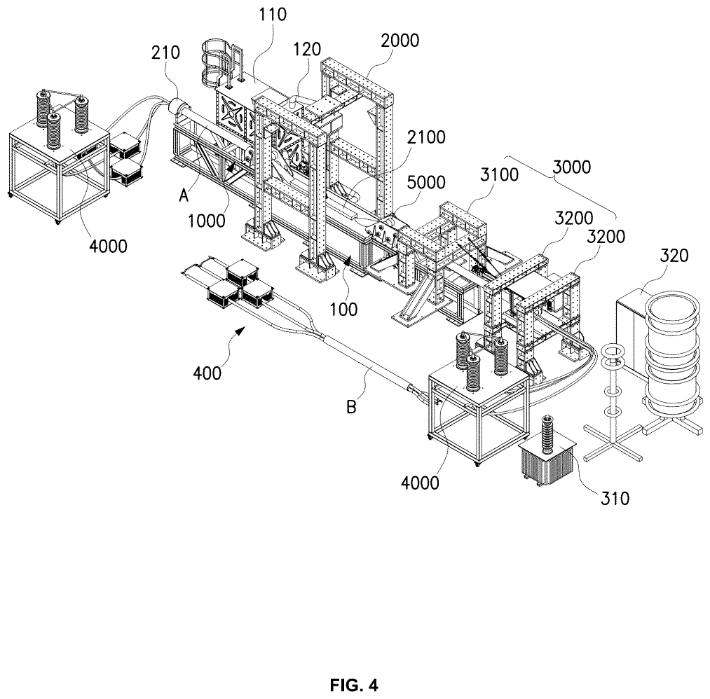

Hereinafter, the present disclosure will be described in more detail with reference to FIGS. 4 to 8.

As illustrated in FIG. 4, the technical purpose of the system for a submarine cable thermal-electrical-mechanical composite test of the present disclosure is to build a test system capable of simultaneously conducting thermal, electrical, and mechanical tests in an environment similar to the installation environment of an actual dynamic cable.

First, in order to conduct a mechanical test, a floor structure 1000 in which multiple frame bars are assembled is formed, a seawater tank module 10 is disposed in the central portion of the floor structure 1000, and a pressing structure 2000 is formed on the seawater tank module 10. In addition, the fixing end 210 which clamps the test cable A is disposed on a first end portion of the floor structure 1000, and an action end structure 3000 on which the action end 220 which clamps the test cable A is disposed is formed on a second end portion thereof.

In addition, a cable end processing frame 4000 for applying a voltage to a cable core wire from which the armor layer is removed is formed on each of opposite ends of the test system.

In addition, it may be seen that a pressure tester 310 and a pressure tester control device 320 that controls the pressure tester are formed in order to conduct an electrical test, and it may be seen that the dummy cable B formed independently from the test cable A is formed in order to conduct a thermal test.

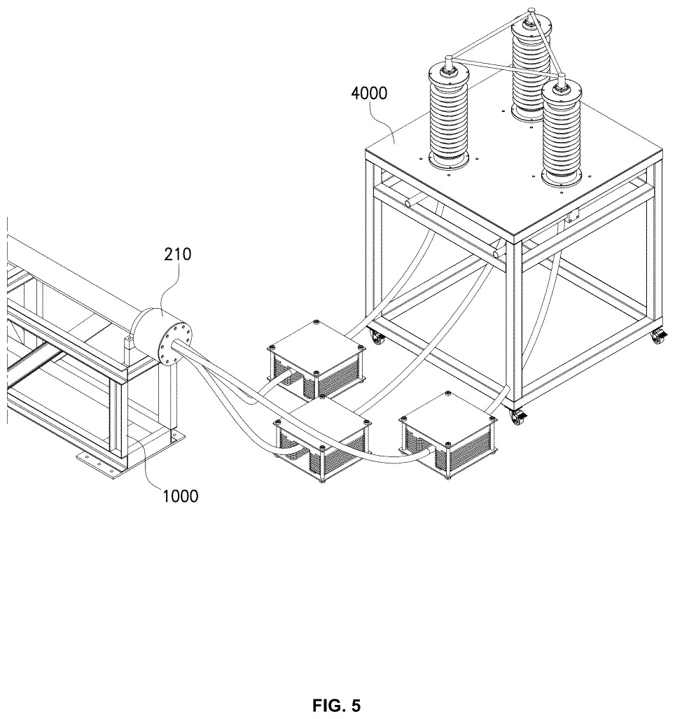

As illustrated in FIG. 5, it may be seen that the fixing end 210 and the action end 220 fixedly clamp the armor layer, which is the outer metal tube of a cable.

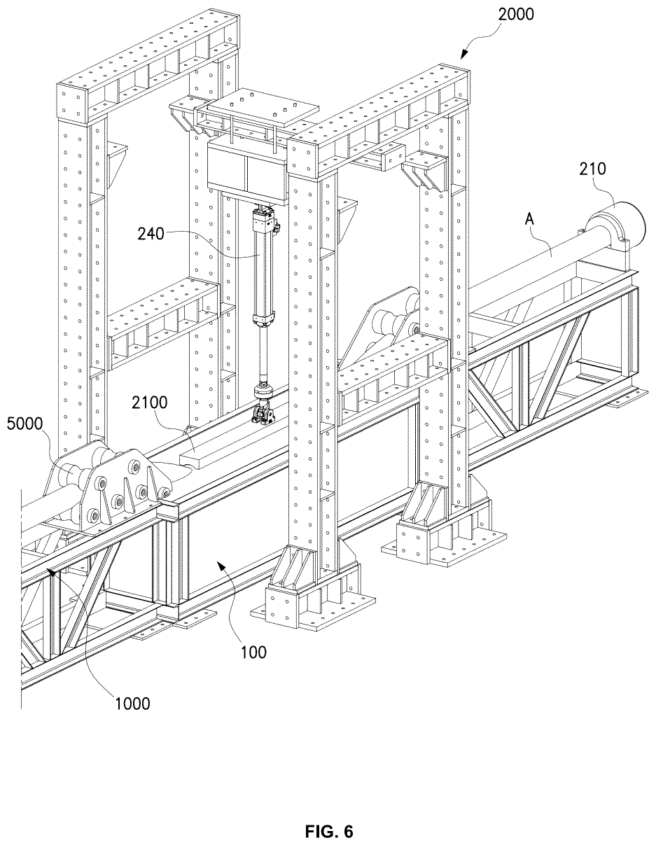

As illustrated in FIG. 6, a cable support wheel 5000 is formed on each of the opposite ends of the seawater tank module 10 to prevent the excessive bending of the test cable and to form a cable curvature similar to the installation environment of an actual cable.

In addition, the vertical actuator 240 is disposed on the upper end of the pressing structure 2000 and presses the test cable A located under vertical actuator 240 by vertical movement. In this case, a pressing member 2100 is disposed to distribute a pressing force applied on the test cable A.

The pressing member 2100 is formed in a semicircular shape so that the deformation of the test cable due to a mechanical stress in an underwater environment is similarly simulated, and the lower surface of the pressing member 2100 in contact with the test cable is also formed to have a semicircular inner groove to prevent the escape of the test cable and perform the protection of the test cable.

Rings formed on the opposite ends of the main body of the pressing member 2100 are connected to the test cable A, and the shape of the main body may be formed into various shapes such as a pentahedron, a hexahedron, or a cylinder, etc.

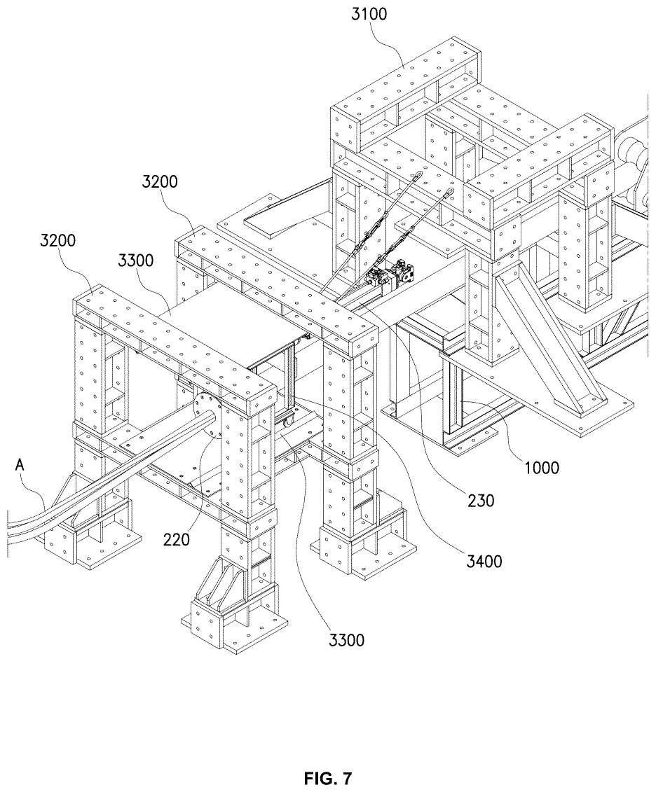

As illustrated in FIG. 7, it can be seen that the action end structure 3000 in which the action end 220 is disposed is formed on the second end part of the floor structure 1000.

The action end structure 3000 includes a first structure 3100 formed on the second end part of the floor structure 1000, a plurality of second structures 3200 which are spaced apart from the first structure 3100 and are disposed by being formed continuously, and a rail guide plate 3300 and a movable member 3400 formed between the second structures 3200. In this case, the action end 220 for fixing and clamping the test cable A is formed on the movable member 3400, and the first structure 3100 and the movable member 3400 are connected to the horizontal actuator 230. The horizontal actuator 230 is driven on the rail of the rail guide plate 3300 formed in the longitudinal direction of the test cable A, and thus the moving direction thereof is restrained in the longitudinal direction of the test cable A, so that the action end 220 of the test cable A may move horizontally, and accordingly, the tensile stress test and tensile bending test of the test cable A are performed.

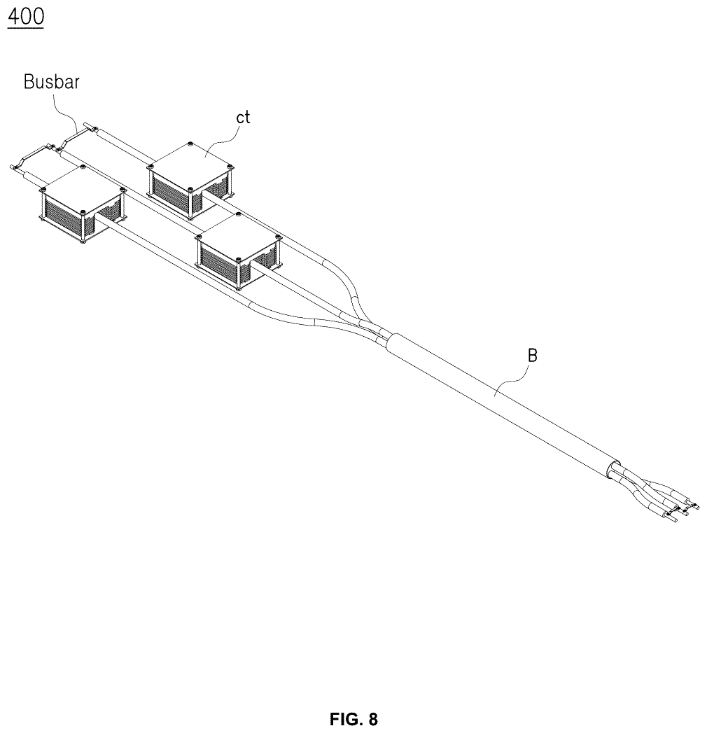

As illustrated in FIG. 8, the dummy cable B is formed independently of the test cable A, with a CT assigned to each phase, and busbars installed on R, S, and T phases.

When a three-phase current is applied to the dummy cable B, heat is generated, and the temperature of the dummy cable B is measured by the temperature sensor (not shown) to predict the temperature of the test cable A, so that a current applied to the test cable A may be adjusted.

Accordingly, the system for a submarine cable thermal-electrical-mechanical composite test of the present disclosure may conduct a test in which mechanical, electrical, and thermal stresses are simultaneously applied to an actual dynamic cable in a seawater environment to create an environment similar to the installation environment of the actual dynamic cable.

The performance evaluation results of a dynamic cable obtained through the present disclosure have the advantage of ensuring reliability, securing quality, and improving durability.

The drawings illustrated for the purpose of explaining the present disclosure above are one embodiment in which the present disclosure is embodied, and it may be known that various combinations are possible in order to realize the gist of the present disclosure as illustrated in the drawings.

Accordingly, the present disclosure is not limited to the above-described embodiments, and as claimed in the following claims, it may be said that the technical spirit of the present disclosure exists to the extent that anyone with ordinary skill in the art to which the present disclosure pertains may make various modifications without departing from the gist of the present disclosure.

What is claimed is:

1. A system for a submarine cable thermal-electrical-mechanical composite test, the system comprising:
a seawater tank module configured to form a seawater environment for a test cable;
a mechanical test module configured to perform mechanical aging of the test cable according to an actuator operation by forming a fixing end and an action end on the test cable;
an electrical test module configured to perform electrical aging of the test cable by applying a voltage to each of opposite ends of the test cable;
a thermal test module configured to measure heat of the dummy cable generated while applying a current to a dummy cable formed independently of the test cable and to apply the current to the test cable while monitoring the heat as generated heat of the test cable; and
a control module configured to perform data input, control processing, monitoring, and storage of the seawater tank module, the mechanical test module, the thermal test module, and the electrical test module,
so that mechanical, thermal, and electrical tests on a dynamic cable are simultaneously performed.

2. The system of claim 1, wherein the seawater tank module comprises:
a seawater tank in which the test cable is immersed; and
a storage tank connected to a pipe controlled by a control valve.

3. The system of claim 1, wherein the fixing end and the action end fixedly clamp an armor layer that protects an inner wire of the test cable.

4. The system of claim 1, wherein in the mechanical test module,
a vertical actuator that is formed on an upper end of the seawater tank module and presses the test cable, and a horizontal actuator that performs a horizontal movement on a side of the action end operate in cooperation with each other to simulate mechanical aging caused by water flow.

5. The system of claim 4, wherein a pressing member that presses the test cable is formed on the vertical actuator,
wherein the pressing member is formed to have a semicircular shape in a longitudinal direction of the test cable, and
a semicircular inner groove conforming to the test cable is formed on a surface of the pressing member in contact with the test cable.

6. The system of claim 4, wherein the horizontal actuator is driven on a rail formed in a longitudinal direction of the test cable, and thus a moving direction thereof is restrained in the longitudinal direction of the test cable.

7. The system of claim 1, wherein the control module comprises:
an input part configured to input necessary information for performing the submarine cable thermal-electrical-mechanical composite test;
a current control part configured to monitor the current applied to the dummy cable and heat generated therein and to apply the current to the test cable based on an amount of the generated heat;
a voltage control part configured to control a voltage applied to the test cable;
a motion control part configured to control the actuator operation;
a seawater control part configured to control a water level of the seawater tank module; and
a memory part configured to store data acquired from the input part, the current control part, the voltage control part, the motion control part, and the seawater control part.
